(19) United States
(12) Patent Application Publication
(10) Pub. No.: US 2010/0140680 A1
(43) Pub. Date: Jun. 10, 2010

(54) Double Polysilicon Process for Non-Volatile Memory

(75) Inventors: Jeong Y. Choi, Palo Alto, CA (US); Kameswara K. Rao, San Jose, CA (US)

Correspondence Address: LNG/MoSys Joint Customer;C/O Luedeka, Neely & Graham, P.C., P.O. BOX 1871, Knoxville, TN, 37923, US

(73) Assignee: MoSys, Inc., Sunnyvale, CA (US)

(21) Appl. No.: 12/331,263

(22) Filed: Dec. 9, 2008

(51) Int. Cl. H01L 29/788; H01L 21/336

(52) U.S. Cl. 257/316; 438/257; 257/E21.422; 257/E29.3

(57) ABSTRACT

A process flow for creating a non-volatile memory cell, the process flow including the steps of forming a doped well in a semiconducting portion of a substrate, forming a gate dielectric layer on top of the substrate, depositing a first polysilicon layer on top of the gate dielectric layer, patterning and etching the first polysilicon layer, selectively oxidizing the first polysilicon layer, implanting lightly-doped source/drain regions into the well, forming sidewall spacers adjacent the first polysilicon layer, implanting source/drain regions into the well, thereby forming a channel area, depositing a dielectric layer on top of the first polysilicon layer, depositing a second polysilicon layer on top of the dielectric layer, forming a masking layer on the second polysilicon layer, and etching both the second polysilicon layer and the dielectric layer using the masking layer.

### FIELD

This invention relates to the field of integrated circuits. More particularly, this invention relates to simplifying a process flow for forming non-volatile memory devices, and thereby reducing the fabrication costs for such devices.

### BACKGROUND

Integrated circuits are typically fabricated using photolithographic techniques, where a layer is formed on a substrate, a pattern is transferred to a layer of photoresist on top of the layer, and the layer is altered in some manner, as defined by the pattern in the photoresist. These basic steps are repeated over and over again, until the integrated circuit is formed.

As the term is used herein, “integrated circuit” includes devices such as those formed on monolithic semiconducting substrates, such as those formed of group IV materials like silicon or germanium, or group III-V compounds like gallium arsenide, or mixtures of such materials. The term includes all types of devices formed, such as memory and logic, and all designs of such devices, such as MOS and bipolar. The term also comprehends applications such as flat panel displays, solar cells, and charge coupled devices.

Transistors operate by either impeding or permitting a flow of current between a source contact and a drain contact. The current is controlled by applying or removing a threshold potential on a gate contact. When the potential to the gate contact is removed or otherwise discontinued, the state of the transistor typically changes. Non-volatile memory is a type of memory that does not require a constant application of the potential to the gate contact in order for the transistor to retain its state. This functionality is typically provided by a so-called floating gate, where the gate is formed with two conductive elements that are vertically separated with an intervening dielectric material.

Adding the second gate element to a standard memory design typically requires the addition of several steps for depositing layers, transferring patterns to the layers, and modifying the layers, as briefly introduced above. Also as mentioned above, adding such steps tends to increase the fabrication costs for such devices.

What is needed, therefore, is a system for producing non-volatile memory that overcomes problems, such as that described above, at least in part.

### SUMMARY

The above and other needs are met by a process flow for creating a non-volatile memory cell, the process flow including the steps of forming a doped well in a semiconducting portion of a substrate, forming a gate dielectric layer on top of the substrate, depositing a first polysilicon layer on top of the gate dielectric layer, patterning and etching the first polysilicon layer, optionally oxidizing the first polysilicon layer, implanting lightly-doped source/drain regions into the well, forming sidewall spacers adjacent the first polysilicon layer, implanting source/drain regions into the well, thereby forming a channel area, depositing a dielectric layer on top of the first polysilicon layer, depositing a second polysilicon layer on top of the dielectric layer, forming a masking layer on the second polysilicon layer, etching both the second polysilicon layer and the dielectric layer using the masking layer, and optionally performing a salicide process.

In this manner, the formation of the second polysilicon structure for the floating gate is inserted into the process flow in a manner where only a single additional masking step is required. Further, the added steps are selected from processes that already exist and are used elsewhere in a standard flow for a single polysilicon gate device. Thus, there is very little overhead associated with the addition of the floating gate design for the device when the presently disclosed process flow is used.

In various embodiments according to this aspect of the invention, the dielectric layer is a film stack of a lower silicon oxide layer, an upper silicon oxide layer, and a silicon nitride layer disposed between the lower silicon oxide layer and the upper silicon oxide layer. In some embodiments the lower silicon oxide layer has a thickness of about fifty angstroms, the upper silicon oxide layer has a thickness of about fifty angstroms, and the silicon nitride layer has a thickness of about seventy angstroms. In some embodiments the second polysilicon layer has a thickness of about five hundred angstroms. Also disclosed is a non-volatile memory cell formed according to the process flows described herein, and an integrated circuit including the non-volatile memory cell.

According to another aspect of the invention there is described a process flow for creating a non-volatile memory cell, the process flow including the steps of forming a doped well in a semiconducting portion of a substrate, forming a gate dielectric layer on top of the substrate, depositing a first polysilicon layer on top of the gate dielectric layer, optionally implanting a dopant species into the first polysilicon layer, patterning and etching the first polysilicon layer, optionally oxidizing the first polysilicon layer, implanting lightly-doped source/drain regions into the well, depositing a dielectric layer on top of the first polysilicon layer, depositing a second polysilicon layer on top of the dielectric layer, forming a masking layer on the second polysilicon layer, etching both the second polysilicon layer and the dielectric layer using the masking layer, forming sidewall spacers adjacent the first polysilicon layer, the dielectric layer, and the second polysilicon layer, implanting source/drain regions into the well, thereby forming a channel area, and optionally performing a salicide process.

According to still another aspect of the invention there is described a process flow for creating a non-volatile memory cell, the process flow including the steps of forming a doped well in a semiconducting portion of a substrate, forming a gate dielectric layer on top of the substrate, depositing a first polysilicon layer on top of the gate dielectric layer, optionally implanting a dopant species into the first polysilicon layer, patterning and etching the first polysilicon layer, depositing a dielectric layer on top of the first polysilicon layer, depositing a second polysilicon layer on top of the dielectric layer, forming a masking layer on the second polysilicon layer, etching both the second polysilicon layer and the dielectric layer using the masking layer, forming an array masking layer on top of the second polysilicon layer, removing the second polysilicon layer and the dielectric layer from logic areas, optionally oxidizing the first polysilicon layer, implanting lightly-doped source/drain regions into the well, forming sidewall spacers adjacent the first polysilicon layer, the dielectric layer, and the second polysilicon layer, implanting source/drain regions into the well, thereby forming a channel area, and optionally performing a salicide process.

According to yet another aspect of the invention there is described a process flow for creating a non-volatile memory cell, the process flow including the steps of forming a doped well in a semiconducting portion of a substrate, forming a gate dielectric layer on top of the substrate, depositing a first polysilicon layer on top of the gate dielectric layer, implanting a dopant species into the first polysilicon layer, forming a floating gate mask, depositing a dielectric layer on top of the first polysilicon layer, depositing a second polysilicon layer on top of the dielectric layer, forming a masking layer on the second polysilicon layer, etching both the second polysilicon layer and the dielectric layer using the masking layer, forming an array masking layer on top of the second polysilicon layer, removing the second polysilicon layer and the dielectric layer from logic areas, patterning and etching the first polysilicon layer, optionally oxidizing the first polysilicon layer, implanting lightly-doped source/drain regions into the well, forming sidewall spacers adjacent the first polysilicon layer, the dielectric layer, and the second polysilicon layer, implanting source/drain regions into the well, thereby forming a channel area, and optionally performing a salicide process.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a cross-sectional side view of a non-volatile memory cell according to a first embodiment of the invention.

FIG. 2 is a top plan view of a non-volatile memory cell according to a first design of the first embodiment of the invention.

FIG. 3 is a top plan view of a non-volatile memory cell according to a second design of the first embodiment of the invention.

FIG. 4 is a cross-sectional side view of a non-volatile memory cell according to a second embodiment of the invention.

FIG. 5 is a top plan view of a non-volatile memory cell according to a first design of the second embodiment of the invention.

FIG. 6 is a top plan view of a non-volatile memory cell according to a second design of the second embodiment of the invention.

FIG. 7 is a cross-sectional side view of a non-volatile memory cell according to a third embodiment of the invention.

FIG. 8 is a top plan view of a non-volatile memory cell according to a first design of the third embodiment of the invention.

FIG. 9 is a top plan view of a non-volatile memory cell according to a second design of the third embodiment of the invention.

### DETAILED DESCRIPTION

In general, the embodiments according to the present invention add steps after the source/drain implantation step, by forming a dielectric layer and a second polysilicon layer over the first patterned polysilicon layer. With one masking step, the dielectric layer and the second polysilicon layer are simultaneously patterned. This can be accomplished with a few different variations, as described in more detail below. However, this reduction in process steps over that which is traditionally required, comes at other types of costs. These trade-offs, and the manner in which they are balanced, are one of the novel aspects of the invention.

For a reasonable coupling ratio from the second polysilicon layer to the floating gate (formed from the first polysilicon layer), the floating gate may be extended over the field oxide region, which results in an increase in the cell size. There exists a trade-off between the cell size and the erase speed (or the requirement of erase bias generated from a charge pump and a regulator). An estimate shows that for a typical process, the coupling ratio will be about forty percent for a smallest possible cell. In order to increase the coupling ratio to a more-desirable eighty percent or so, the cell size is increased by about a factor of three. However, the conventional single-polysilicon approach would result in a cell that is larger by yet another factor of about three.

Thus, fewer masking steps are added by the current process in comparison to other double-polysilicon process flows, so the processing costs are substantially lower with the embodiments described herein, even though the size of the cell is larger than the size of a standard double-polysilicon cell. If the cell is made to be as small as a prior-art double-polysilicon cell, then the coupling ratio would be lower, resulting in a performance hit. However, cell size under the proposed process flow is smaller than that of a single-polysilicon non-volatile memory process, and only costs a bit more than a typical single-polysilicon process flow. These devices are especially suited for applications such as embedded devices, where larger size and lower cost fit the needs of the device quite well.

### Option 1

In this embodiment, the steps by which the upper polysilicon gate 28 is formed are inserted between the source/drain 15/16 implants and the salicide module and subsequent back-end processing.

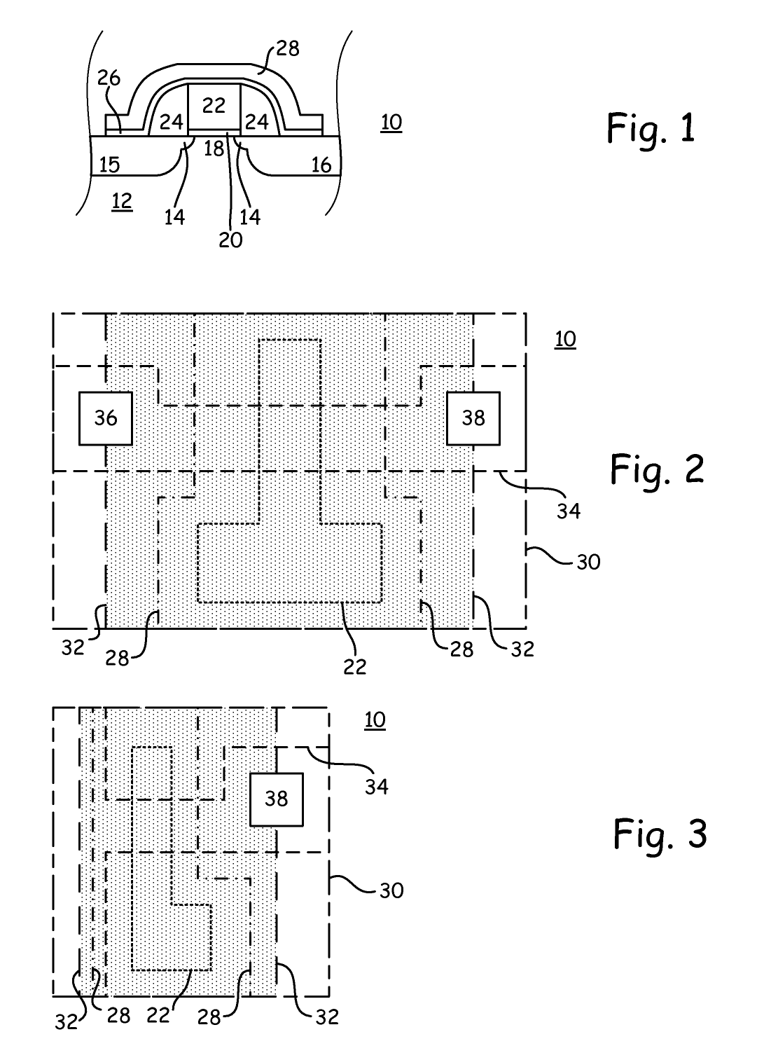

According to the embodiment depicted in FIG. 1, the process flow includes the formation of the memory cell 10 in a well area 12. On top of this there is formed a gate dielectric 20, such as an oxide or nitride of one or more of silicon, hafnium, etc. The first polysilicon layer 22 is then deposited and etched to form the lower gate structure. An oxidation step after the polysilicon etch is an optional step for improving reliability. The well area 12 then receives a doping, such as by ion implantation, to form the lightly-doped source/drain implant areas 14. The sidewall spacers 24 are then formed, such as from an oxide or nitride. This is followed by the implantation of the source/drain regions 15/16. The spacers 24 may be formed of a single layer of oxide or nitride or a composite layer of oxide and nitride. These steps define a channel area 18.

Then, according to this embodiment of the present invention, there is deposited a dielectric layer 26, which in some embodiments is a composite layer, such as about fifty angstroms of silicon oxide, about seventy angstroms of silicon nitride, and about fifty angstroms of silicon oxide. The second polysilicon layer 28 is then deposited. The second polysilicon layer 28 is formed so as to be thin enough to provide conformal covering of the underlying structures without adding unnecessarily to the overall topography of the device 10, while also being sufficiently thick to withstand a subsequent salicidation step. This thickness in some embodiments is about five hundred angstroms.

A photoresist mask is then formed over the substrate, which mask defines structures to be formed in the dielectric layer 26 and the second polysilicon layer 28. Then the dielectric layer 26 and the second polysilicon layer 28 are etched using just that one masking layer. One or more etch processes may be used to etch the various layers, but the same masking layer is used to define the etch areas in all of the layers 26 and 28. This novel process flow can then be followed by a salicidation module, and other back-end processes.

A memory cell 10 produced with this process flow can be optimized for either performance, as depicted in FIG. 2, or for size, as depicted in FIG. 3. FIG. 2 provides a top plan view of a cell 10 according to this process flow option, depicting well boundaries 30, cell boundaries 32, an active area 34, source contact 36, bit line contact 38, the first polysilicon layer 22, and the overlying second polysilicon layer 28. Alignment in the drawing between the cell boundary 32 and other elements, such as the well boundary 30, is not critical. It is appreciated that the control-gate contacts (the contacts for layer 28) are provided at some interval of columns (usually for at least 256 columns). For one embodiment of a 130 nanometer process, this cell 10 has dimensions of about 0.85 microns by about 0.92 microns, for a size of about 0.782 square microns, or about forty-five percent the size of a single layer polysilicon cell with similar functionality.

The cell that is depicted in FIG. 3, which is optimized for size, has dimensions of about 0.73 microns by about 0.87 microns, for a size of about 0.635 square microns, or about thirty-six percent the size of a single polysilicon layer cell. This smaller size is accomplished by only providing a source contact at regular intervals such as for every sixteen or thirty-two columns, and laying out the cell 10 to minimum design rules. It is noted that where the cell boundaries 32 cut through a contact or area, those contacts or areas are shared with adjacent cells 10.

Neither of the two embodiments of FIGS. 2 and 3 provide a salicide-block layer within the cell 10 boundaries, unlike a single-polysilicon cell that requires salicidation blocking on the floating gate. However, the floating gate 22 is completely sealed by the second polysilicon layer 26 and the spacers 24. Neighboring cells share the bit line contact 38, as depicted in each of FIGS. 2 and 3. This process flow option adds only a single masking step and the deposition and etch of the dielectric layer 28 and the second polysilicon layer 26 to the standard single-polysilicon process flow. Many of the cells 10, perhaps in conjunction with cells of other types, form an integrated circuit, a portion of which is depicted in FIGS. 1-3.

### Option 2

In this embodiment, the steps by which the upper polysilicon gate 28 is formed are inserted between the lightly-doped source/drain implant 14 steps and the formation of the sidewall spacers 24.

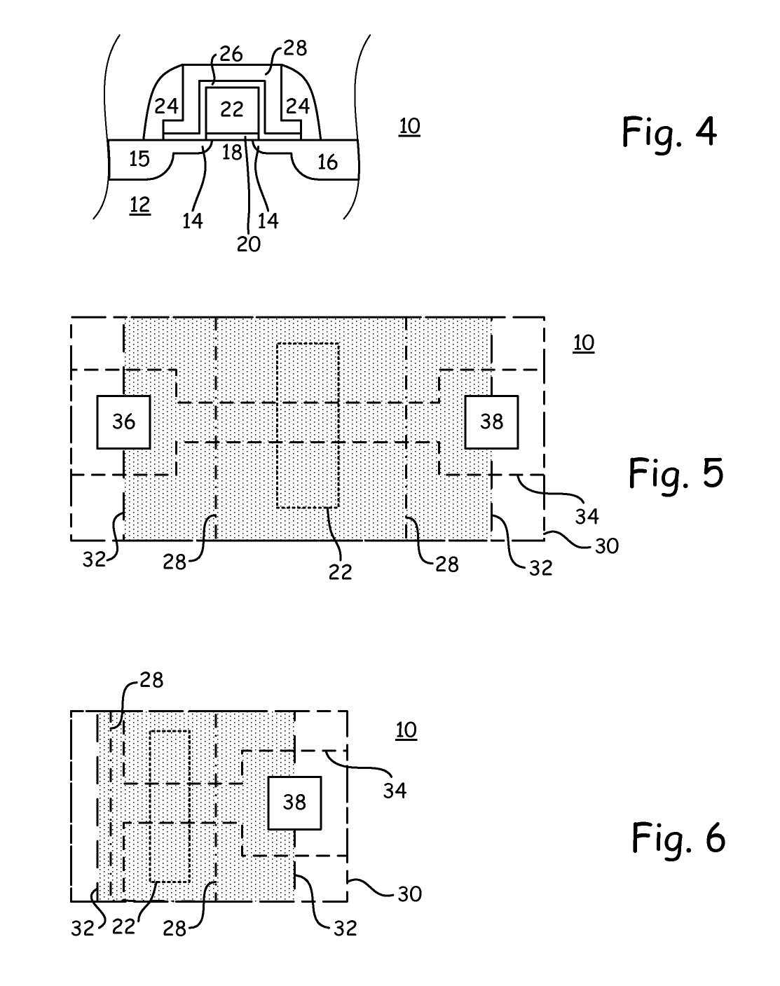

According to the embodiment depicted in FIG. 4, the process flow includes the formation of the memory cell 10 in a well area 12. On top of this there is formed a gate dielectric 20. The first polysilicon layer 22 is then deposited (with an optional poly dope implant for the memory cell, preferably n-type) and etched to form the lower gate structure. The well area 12 then receives a doping, such as by ion implantation, to form the lightly-doped source/drain implant areas 14.

Then, according to this embodiment of the present invention, there is deposited a dielectric layer 26, which in some embodiments is a composite layer, such as about fifty angstroms of silicon oxide, about seventy angstroms of silicon nitride, and about fifty angstroms of silicon oxide. The second polysilicon layer 28 is then deposited. The second polysilicon layer 28 is formed so as to be thin enough to provide conformal covering of the underlying structures without adding unnecessarily to the overall topography of the device 10, while also being sufficiently thick to withstand a subsequent salicidation step. This thickness in some embodiments is about five hundred angstroms.

A photoresist mask is then formed over the substrate, which mask defines structures to be formed in the dielectric layer 26 and the second polysilicon layer 28. Then the dielectric layer 26 and the second polysilicon layer 28 are etched using just that one masking layer. One or more etch processes may be used to etch the various layers, but the same masking layer is used to define the etch areas in all of the layers 26 and 28.

The sidewall spacers 24 are then formed, followed by the implantation of the source/drain regions 15/16. These steps define a channel area 18. The process flow can be followed by a salicidation process, and other back-end processes.

A memory cell 10 produced with this process flow can be optimized for either performance, as depicted in FIG. 5, or for size, as depicted in FIG. 6. FIG. 5 provides a top plan view of a cell 10 according to this process flow option, depicting the alignment of well boundaries 30, cell boundaries 32, an active area 34, source contact 36, bit line contact 38, the first polysilicon layer 22, and the overlying second polysilicon layer 28. For one embodiment of a 130 nanometer process, this cell 10 has dimensions of about 0.77 microns by about 0.73 microns, for a size of about 0.562 square microns, or about thirty-two percent the size of a single layer polysilicon cell with similar functionality.

The cell that is depicted in FIG. 6 which is optimized for size, has dimensions of about 0.65 microns by about 0.66 microns, for a size of about 0.429 square microns, or about twenty-five percent the size of a single polysilicon layer cell. This smaller size is accomplished by only providing a source contact at regular intervals such as for every sixteen or thirty-two columns, and laying out the cell 10 to minimum design rules. It is noted that where the cell boundaries 32 cut through a contact or area, those contacts or areas are shared with adjacent cells 10.

Neither of the two embodiments of FIGS. 5 and 6 provide salicide-block layer within the cell 10 boundaries. However, the floating gate 22 is completely sealed by the second polysilicon layer 26. Neighboring cells share the bit line contact 38, as depicted in each of FIGS. 5 and 6. This process flow option adds only a single masking step and the deposition and etch of the dielectric layer 28 and the second polysilicon layer 26 to the standard single-polysilicon process flow. This embodiment optionally includes a second masking layer for the n+ (or p+) doping of the first polysilicon layer 22. Many of the cells 10, perhaps in conjunction with cells of other types, form an integrated circuit, a portion of which is depicted in FIGS. 4-6.

There is an alternate method for this option 2, depending on the difficulty of removing the layers 28 from the logic area of the device because of the topography that is created when layer 22 is patterned before depositing layers 26 and 28. In this embodiment, at the first polysilicon layer masking step, only the floating gate layer in the memory area is patterned (instead of simultaneously etching the logic gates), the process steps for the second polysilicon layer are then performed, followed by a third polysilicon mask for patterning the first polysilicon layer in the logic area.

### Option 3

In this embodiment, the steps by which the upper polysilicon gate 28 are formed are inserted between the n+ (or p+) doping of the first polysilicon layer 22 and the masking and etching of the first polysilicon layer 22. This option is also called a stacked gate configuration.

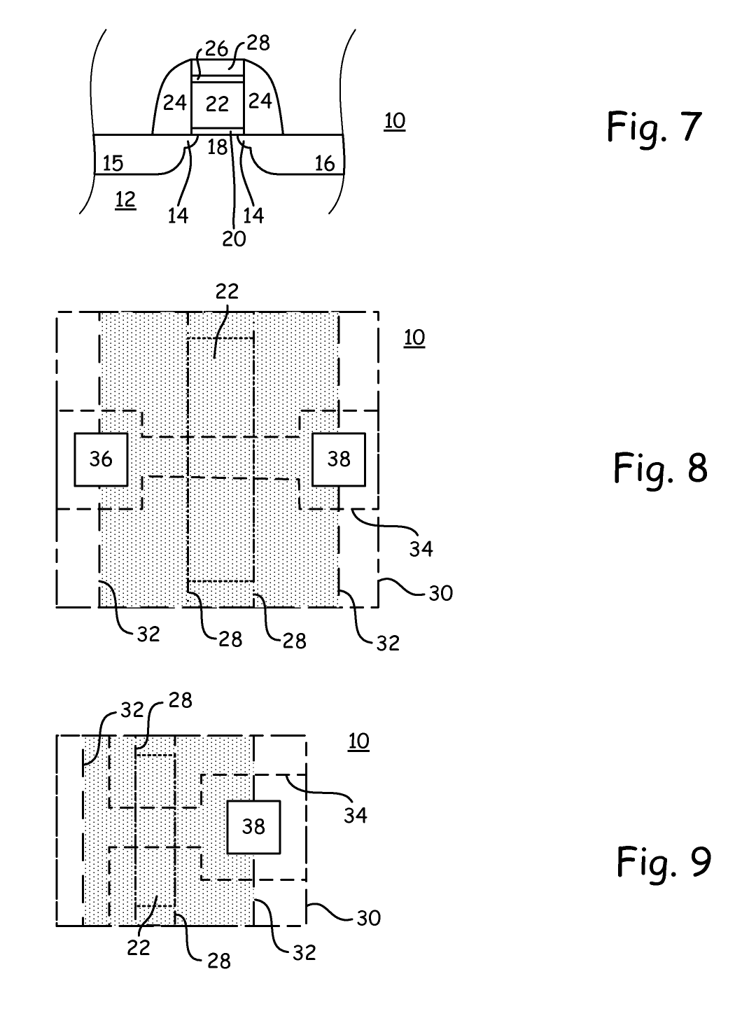

According to the embodiment depicted in FIG. 7, the process flow includes the formation of the memory cell 10 in a well area 12. On top of this there is formed a gate dielectric 20. The first polysilicon layer 22 is then deposited, followed with a polysilicon doping implant. A floating gate photomask is applied for the array to isolate the floating gates 22 between cells 10 in the direction perpendicular to the plan of cross section in FIG. 7. Then, according to this embodiment of the present invention, there is deposited a dielectric layer 26, which in some embodiments is a composite layer, such as about fifty angstroms of silicon oxide, about seventy angstroms of silicon nitride, and about fifty angstroms of silicon oxide. The second polysilicon layer 28 is then deposited. The second polysilicon layer 28 is formed so as to be thin enough to provide conformal covering of the underlying structures without adding unnecessarily to the overall topography of the device 10, while also being sufficiently thick to withstand a subsequent salicidation step. This thickness in some embodiments is about five hundred angstroms.

A photoresist mask is then formed over the substrate, which mask defines structures to be formed in the dielectric layer 26 and the second polysilicon layer 28. Then the dielectric layer 26 and the second polysilicon layer 28 are etched using just that one masking layer. One or more etch processes may be used to etch the various layers, but the same masking layer is used to define the etch areas in all of the layers 26 and 28. In one embodiment layers 26 and 28 are etched non-selectively until the etch approaches the bottom of layer 22, at which time the etch process switches to very selective etch (polysilicon etch selective to oxide), so that the source/drain regions are protected.

An array protection mask is applied, and the second polysilicon layer 28 and the dielectric layer 26 are removed from the logic area. Then the first polysilicon layer 22 is masked, etched, and oxidized to form the logic gate structure. The well area 12 then receives a doping, such as by ion implantation, to form the lightly-doped source/drain implant areas 14. The sidewall spacers 24 are then formed, followed by the implantation of the source/drain regions 15/16. These steps define a channel area 18.

A memory cell 10 produced with this process flow can be optimized for either performance, as depicted in FIG. 8, or for size, as depicted in FIG. 9. FIG. 8 provides a top plan view of a cell 10 according to this process flow option, depicting well boundaries 30, cell boundaries 32, an active area 34, source contact 36, bit line contact 38, the first polysilicon layer 22, and the overlying second polysilicon layer 28. For one embodiment of a 130 nanometer process, this cell 10 has dimensions of about 0.57 microns by about 0.73 microns, for a size of about 0.416 square microns, or about twenty-four percent the size of a single layer polysilicon cell with similar functionality.

The cell that is depicted in FIG. 9 which is optimized for size, has dimensions of about 0.51 microns by about 0.7 microns, for a size of about 0.357 square microns, or about twenty percent the size of a single polysilicon layer cell. This smaller size is accomplished by only providing a source contact at regular intervals such as for every sixteen or thirty-two columns, and laying out the cell 10 to minimum design rules. It is noted that where the cell boundaries 32 cut through a contact or area, those contacts or areas are shared with adjacent cells 10.

Neither of the two embodiments of FIGS. 8 and 9 provide salicide-block layer within the cell 10 boundaries. Instead, the floating gate 22 is completely sealed by the second polysilicon layer 26 and the polysilicon oxidation. Neighboring cells share the bit line contact 38, as depicted in each of FIGS. 8 and 9. This process flow option adds two or three masking steps and the deposition and etch of the dielectric layer 28 and the second polysilicon layer 26 to the standard single-polysilicon process flow. Many of the cells 10, perhaps in conjunction with cells of other types, form an integrated circuit, a portion of which is depicted in FIGS. 7-9.

In a slight variation, the steps by which the upper polysilicon gate 28 are formed are inserted between the etch of the first polysilicon layer 22 and the oxidation of the first polysilicon layer 22.

There is an alternate method for this option 3, depending on the difficulty of removing the layers 28 from the logic area of the device because of the topography that is created when layer 22 is patterned before depositing layers 26 and 28. In this embodiment, at the first polysilicon layer masking step, the first polysilicon layer 22 is etched simultaneously in both the memory and logic areas, layers 26 and 28 are deposited, the mask as discussed in paragraph [0044] is used to pattern the layers 28/26/22 in the memory area, and the array protection mask as discussed in paragraph

is used to remove layers 28 and 26 in the logic area.

The foregoing description of preferred embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A process flow for creating a non-volatile memory cell, the process flow comprising the steps of:
forming a doped well in a semiconducting portion of a substrate,
forming a gate dielectric layer on top of the substrate,
depositing a first polysilicon layer on top of the gate dielectric layer,
patterning and etching the first polysilicon layer,
forming lightly-doped source/drain regions into the well,
forming sidewall spacers adjacent the first polysilicon layer,
implanting source/drain regions into the well,
depositing a dielectric layer on top of the first polysilicon layer,
depositing a second polysilicon layer on top of the dielectric layer,
forming a masking layer on the second polysilicon layer, and
etching both the second polysilicon layer and the dielectric layer using the masking layer.

2. The process flow of claim 1, further comprising the step of oxidizing the first polysilicon layer after the step of patterning and etching the first polysilicon layer.

3. The process flow of claim 1, further comprising the step of selectively doping the first polysilicon layer before patterning and etching the first polysilicon layer.

4. The process flow of claim 1, wherein the dielectric layer comprises a film stack of a lower silicon oxide layer, an upper silicon oxide layer, and a silicon nitride layer disposed between the lower silicon oxide layer and the upper silicon oxide layer.

5. The process flow of claim 1, wherein the dielectric layer comprises a film stack of a lower silicon oxide layer having a thickness of about fifty angstroms, an upper silicon oxide layer having a thickness of about fifty angstroms, and a silicon nitride layer having a thickness of about seventy angstroms disposed between the lower silicon oxide layer and the upper silicon oxide layer.

6. The process flow of claim 1, wherein the second polysilicon layer has a thickness of about five hundred angstroms.

7. The process flow of claim 1, wherein the first polysilicon layer has a thickness of more than about five hundred angstroms and less than about three thousand angstroms.

8. The process flow of claim 1, wherein the first polysilicon layer forms gates for at least a portion of a logic area.

9. A non-volatile memory cell formed according to the process flow of claim 1.

10. An integrated circuit including a non-volatile memory cell formed according to the process flow of claim 1.

11. A process flow for creating a non-volatile memory cell, the process flow comprising the steps of:
forming a doped well in a semiconducting portion of a substrate,
forming a gate dielectric layer on top of the substrate,
depositing a first polysilicon layer on top of the gate dielectric layer,
patterning and etching the first polysilicon layer,
forming lightly-doped spurce/drain regions into the well,
depositing a dielectric layer on top of the first polysilicon layer,
depositing a second polysilicon layer on top of the dielectric layer,
forming a masking layer on the second polysilicon layer,
etching both the second polysilicon layer and the dielectric layer using the masking layer,
forming sidewall spacers adjacent the first polysilicon layer, the dielectric layer, and the second polysilicon layer, and
implanting source/drain regions into the well.

12. The process flow of claim 11, further comprising the step of oxidizing the first polysilicon layer after the step of patterning and etching the first polysilicon layer.

13. The process flow of claim 11, further comprising the step of selectively doping the first polysilicon layer before patterning and etching the first polysilicon layer.

14. The process flow of claim 11, wherein the dielectric layer comprises a film stack of a lower silicon oxide layer, an upper silicon oxide layer, and a silicon nitride layer disposed between the lower silicon oxide layer and the upper silicon oxide layer.

15. The process flow of claim 11, wherein the dielectric layer comprises a film stack of a lower silicon oxide layer having a thickness of about fifty angstroms, an upper silicon oxide layer having a thickness of about fifty angstroms, and a silicon nitride layer having a thickness of about seventy angstroms disposed between the lower silicon oxide layer and the upper silicon oxide layer.

16. The process flow of claim 11, wherein the second polysilicon layer has a thickness of about five hundred angstroms.

17. The process flow of claim 11, wherein the first polysilicon layer has a thickness of more than about five hundred angstroms and less than about three thousand angstroms.

18. The process flow of claim 11, wherein the first polysilicon layer forms gates for at least a portion of a logic area.

19. A non-volatile memory cell formed according to the process flow of claim 11.

20. An integrated circuit including a non-volatile memory cell formed according to the process flow of claim 11.

21. A process flow for creating a non-volatile memory cell, the process flow comprising the steps of:
forming a doped well in a semiconducting portion of a substrate,
forming a gate dielectric layer on top of the substrate,
depositing a first polysilicon layer on top of the gate dielectric layer,
patterning and etching the first polysilicon layer,
performing a blanket implant to form lightly-doped source/drain regions in the non-volatile memory cell,
depositing a dielectric layer on top of the first polysilicon layer,
depositing a second polysilicon layer on top of the dielectric layer,
forming a masking layer on the second polysilicon layer,
etching both the second polysilicon layer and the dielectric layer,
patterning and etching the first polysilicon layer in logic areas,
forming lightly-doped source/drain regions into the well,
forming sidewall spacers adjacent the first polysilicon layer, the dielectric layer, and the second polysilicon layer, and
implanting source/drain regions into the well.

22. The process flow of claim 21, further comprising the step of oxidizing the first polysilicon layer after the step of removing the second polysilicon layer and the dielectric layer from logic areas.

23. The process flow of claim 21, further comprising the step of selectively doping the first polysilicon layer before patterning and etching the first polysilicon layer.

24. The process flow of claim 21, further comprising the step of etching the gate dielectric layer using the masking layer after the step of etching both the second polysilicon layer and the dielectric layer.

25. The process flow of claim 21, wherein the dielectric layer comprises a film stack of a lower silicon oxide layer, an upper silicon oxide layer, and a silicon nitride layer disposed between the lower silicon oxide layer and the upper silicon oxide layer.

26. The process flow of claim 21, wherein the dielectric layer comprises a film stack of a lower silicon oxide layer having a thickness of about fifty angstroms, an upper silicon oxide layer having a thickness of about fifty angstroms, and a silicon nitride layer having a thickness of about seventy angstroms disposed between the lower silicon oxide layer and the upper silicon oxide layer.

27. The process flow of claim 21, wherein the second polysilicon layer has a thickness of about five hundred angstroms.

28. The process flow of claim 21, wherein the first polysilicon layer has a thickness of more than about five hundred angstroms and less than about three thousand angstroms.

29. The process flow of claim 21, wherein the first polysilicon layer forms gates for at least a portion of a logic area.

30. A non-volatile memory cell formed according to the process flow of claim 21.

31. An integrated circuit including a non-volatile memory cell formed according to the process flow of claim 21.

32. A process flow for creating a non-volatile memory cell, the process flow comprising the steps of:
forming a doped well in a semiconducting portion of a substrate,
forming a gate dielectric layer on top of the substrate,
depositing a first polysilicon layer on top of the gate dielectric layer,
selectively implanting a dopant species into the first polysilicon layer,
forming a floating gate mask,
selectively etching the first polysilicon layer using the floating gate mask,
depositing a dielectric layer on top of the first polysilicon layer,
depositing a second polysilicon layer on top of the dielectric layer,
forming a masking layer on the second polysilicon layer,
selectively etching the second polysilicon layer, the dielectric layer using the masking layer, and the first polysilicon layer,
forming an array masking layer on top of the second polysilicon layer,
removing the second polysilicon layer and the dielectric layer from logic areas,
patterning and etching the first polysilicon layer,
forming lightly-doped source/drain regions into the well,
forming sidewall spacers adjacent the first polysilicon layer, the dielectric layer, and the second polysilicon layer, and
implanting source/drain regions into the well.

33. The process flow of claim 32, further comprising the step of oxidizing the first polysilicon layer after the step of patterning and etching the first polysilicon layer.

34. The process flow of claim 32, wherein the dielectric layer comprises a film stack of a lower silicon oxide layer, an upper silicon oxide layer, and a silicon nitride layer disposed between the lower silicon oxide layer and the upper silicon oxide layer.

35. The process flow of claim 32, wherein the dielectric layer comprises a film stack of a lower silicon oxide layer having a thickness of about fifty angstroms, an upper silicon oxide layer having a thickness of about fifty angstroms, and a silicon nitride layer having a thickness of about seventy angstroms disposed between the lower silicon oxide layer and the upper silicon oxide layer.

36. The process flow of claim 32, wherein the second polysilicon layer has a thickness of about five hundred angstroms.

37. The process flow of claim 32, wherein the first polysilicon layer has a thickness of more than about five hundred angstroms and less than about three thousand angstroms.

38. The process flow of claim 32, wherein the first polysilicon layer forms gates for at least a portion of a logic area.

39. A non-volatile memory cell formed according to the process flow of claim 32.

40. An integrated circuit including a non-volatile memory cell formed according to the process flow of claim 32.

41. A process flow for creating a non-volatile memory cell, the process flow comprising the steps of:
forming a doped well in a semiconducting portion of a substrate,
forming a gate dielectric layer on top of the substrate,
depositing a first polysilicon layer on top of the gate dielectric layer,
selectively implanting a dopant species into the first polysilicon layer,
patterning and etching the first polysilicon layer,
depositing a dielectric layer on top of the first polysilicon layer,
depositing a second polysilicon layer on top of the dielectric layer,
forming a masking layer on the second polysilicon layer,
selectively etching the second polysilicon layer, the dielectric layer using the masking layer, and the first polysilicon layer,
forming an array masking layer on top of the second polysilicon layer,
removing the second polysilicon layer and the dielectric layer from logic areas,
forming lightly-doped source/drain regions into the well,
forming sidewall spacers adjacent the first polysilicon layer, the dielectric layer, and the second polysilicon layer, and
implanting source/drain regions into the well.

42. The process flow of claim 41, further comprising the step of oxidizing the first polysilicon layer after the step of patterning and etching the first polysilicon layer.

43. The process flow of claim 41, wherein the dielectric layer comprises a film stack of a lower silicon oxide layer, an upper silicon oxide layer, and a silicon nitride layer disposed between the lower silicon oxide layer and the upper silicon oxide layer.

44. The process flow of claim 41, wherein the dielectric layer comprises a film stack of a lower silicon oxide layer having a thickness of about fifty angstroms, an upper silicon oxide layer having a thickness of about fifty angstroms, and a silicon nitride layer having a thickness of about seventy angstroms disposed between the lower silicon oxide layer and the upper silicon oxide layer.

45. The process flow of claim 41, wherein the second polysilicon layer has a thickness of about five hundred angstroms.

46. The process flow of claim 41, wherein the first polysilicon layer has a thickness of more than about five hundred angstroms and less than about three thousand angstroms.

47. The process flow of claim 41, wherein the first polysilicon layer forms gates for at least a portion of a logic area.

48. A non-volatile memory cell formed according to the process flow of claim 41.

49. An integrated circuit including a non-volatile memory cell formed according to the process flow of claim 41.

50. A non-volatile memory cell, comprising:
a semiconducting substrate,
a source portion formed in the semiconducting substrate,
a drain portion formed in the semiconducting substrate,
an active area formed in the semiconducting substrate and extending in a strip in x-coordinate directions between the source portion and the drain portion, and
a first polysilicon gate layer formed above the semiconducting substrate and crossing the active area in y-coordinate directions between the source portion and the drain portion, the gate extending outside the strip of the active area in both of the y-coordinate directions.

51. The non-volatile memory cell of claim 50, further comprising a second polysilicon gate layer formed above and completely overlying the first polysilicon gate layer and extending beyond the first polysilicon gate layer in at least one of the x-coordinate directions and the y-coordinate directions.

52. The non-volatile memory cell of claim 50, further comprising a second polysilicon gate layer formed above and completely overlying the first polysilicon gate layer and extending beyond the first polysilicon gate layer in all of the x-coordinate directions and the y-coordinate directions.
